(19) United States
(12) Patent Application Publication
(10) Pub. No.: US 2023/0261437 A1
(43) Pub. Date: Aug. 17, 2023

(54) PATTERNED WAFER MICRORULER FOR OVERSPRAY SCREENING OF LASER ANTI-REFLECTIVE AND/OR HIGHLY REFLECTIVE FACET COATINGS

(71) Applicant: Lumentum Operations LLC, San Jose, CA (US)

(72) Inventors: ZiWen DONG, San Ramon, CA (US); Hery DJIE, San Jose, CA (US); Anuj MADARIA, San Jose, CA (US); Yutong LI, Fremont, CA (US); Ran HUANG, San Jose, CA (US)

(21) Appl. No.: 17/806,991

(22) Filed: Jun. 15, 2022

Related U.S. Application Data
(60) Provisional application No. 63/267,861, filed on Feb. 11, 2022.

(51) Int. Cl. H01S 5/028; H01S 5/02; H01S 5/40

(52) U.S. Cl. CPC H01S 5/0287; H01S 5/0202; H01S 5/4025

(57) ABSTRACT

In some implementations, a microruler is patterned on a surface of a wafer to enable visual overspray screening and/or quantitative measurement. For example, a laser bar cleaved from a wafer may comprise multiple laser devices that each include a first facet and a second facet, an anti-reflective (AR) coating applied to the first facet, and a highly reflective (HR) coating applied to the second facet. Furthermore, a set of microrulers may be patterned on a surface of the laser bar, where each microruler in the set of microrulers is aligned with a bar cleaving line where the laser bar was cleaved from the wafer, and each microruler has multiple graduation markings that each represent a respective distance from the bar cleaving line such that the graduation markings can be used to quantitatively measure an overspray of the AR coating or the HR coating relative to the bar cleaving line.

### CROSS-REFERENCE TO RELATED APPLICATION

This patent application claims priority to U.S. Patent Application No. 63/267,861, filed on Feb. 11, 2022, and entitled “PRINTED WAFER MICRORULER FOR OVERSPRAY SCREENING OF LASER ANTIREFLECTIVE-HIGH REFLECTIVE FACET COATING.” The disclosure of the prior application is considered part of and is incorporated by reference into this patent application.

### TECHNICAL FIELD

The present disclosure relates generally to laser device manufacturing and to a microruler that may be patterned on a surface of a wafer to enable overspray screening for an anti-reflective (AR) and/or highly reflective (HR) coating applied to laser facets.

### BACKGROUND

In a typical manufacturing process, semiconductor lasers are fabricated using a wafer having an appropriate layered structure for an active (e.g., light-generating) region of the laser. The wafer is cut into laser bars, each of which is a one-dimensional array of laser devices. The manufacturing process then involves application of thin films of glasslike materials to the sides, commonly referred to as facets, of the laser bar to define laser cavities. The thin films (e.g., anti-reflective (AR) coatings and/or highly reflective (HR) coatings) are often referred to as facet coatings. Due to the nature of the facet coating process, the coating material can overspray and cover unmasked areas of the laser bar in addition to the facets. In particular, overspray coating the top and/or bottom surfaces of the laser bar is undesirable because the surfaces have bonding (e.g., gold) pads for mechanical and/or electrical connections.

### SUMMARY

In some implementations, a laser bar includes multiple laser devices that each include a first facet at a first end of the laser bar and a second facet at a second end of the laser bar; an anti-reflective (AR) coating applied to the first end of the laser bar; a highly reflective (HR) coating applied to the second end of the laser bar; and a set of microrulers patterned on a surface of the laser bar, wherein each microruler included in the set of microrulers is aligned with a bar cleaving line where the laser bar was cleaved from a wafer, and wherein each microruler has multiple graduation markings that each represent a respective distance from the bar cleaving line for quantitatively measuring an overspray of the AR coating or the HR coating relative to the bar cleaving line.

In some implementations, a laser device includes a laser cavity; a first facet at a first end of the laser cavity; a second facet at a second end of the laser cavity; an AR coating applied to the first facet at the first end of the laser cavity; an HR coating applied to the second facet at the second end of the laser cavity; and a set of microrulers patterned on a surface of the laser device, wherein each microruler included in the set of microrulers is aligned with a location of the first facet or the second facet, and wherein each microruler has multiple graduation markings that each represent a respective distance from the location of the first facet or the second facet for quantitatively measuring an overspray of the AR coating or the HR coating.

In some implementations, a method includes forming a wafer comprising multiple laser bars, wherein the multiple laser bars each include multiple laser devices that each include a first facet at a first end of the respective laser bar and a second facet at a second end of the respective laser bar; patterning a set of microrulers on a surface of the laser bar, wherein each microruler included in the set of microrulers is aligned with a bar cleaving line where the wafer is to be cleaved into the multiple laser bars, and wherein each microruler has multiple graduation markings that each represent a respective distance from a respective bar cleaving line; cleaving the wafer into the multiple laser bars; and applying an AR coating and an HR coating to the multiple laser bars, wherein the multiple graduation markings included in the set of microrulers quantitatively measure an overspray of the AR coating or the HR coating.

### BRIEF DESCRIPTION OF THE DRAWINGS

FIGS. 1A-1D are diagrams of an example process for manufacturing a semiconductor laser device.

FIG. 2A is a diagram of an example of a laser strip device that has an anti-reflective (AR) coating on a first facet and a highly reflective (HR) coating on a second facet.

FIG. 2B is a diagram of an example overspray specification for an AR coating and/or an HR coating applied to one or more facets of a laser device.

FIGS. 3A-3B are diagrams of one or more example implementations of a microruler that may be patterned on a surface of a laser device to enable overspray screening for an AR coating and/or an HR coating applied to one or more facets of the laser device.

FIG. 4 is a diagram of an example implementation of a two-dimensional microruler design that can be used for wire-bonding, laser welding, and/or epoxy contact area screening.

FIG. 5 is a flowchart of an example process to fabricate laser bars that have a microruler patterned on a surface of the laser bars to enable overspray screening for an AR coating and/or an HR coating applied to one or more facets of the laser bars.

### DETAILED DESCRIPTION

The following detailed description of example implementations refers to the accompanying drawings. The same reference numbers in different drawings may identify the same or similar elements.

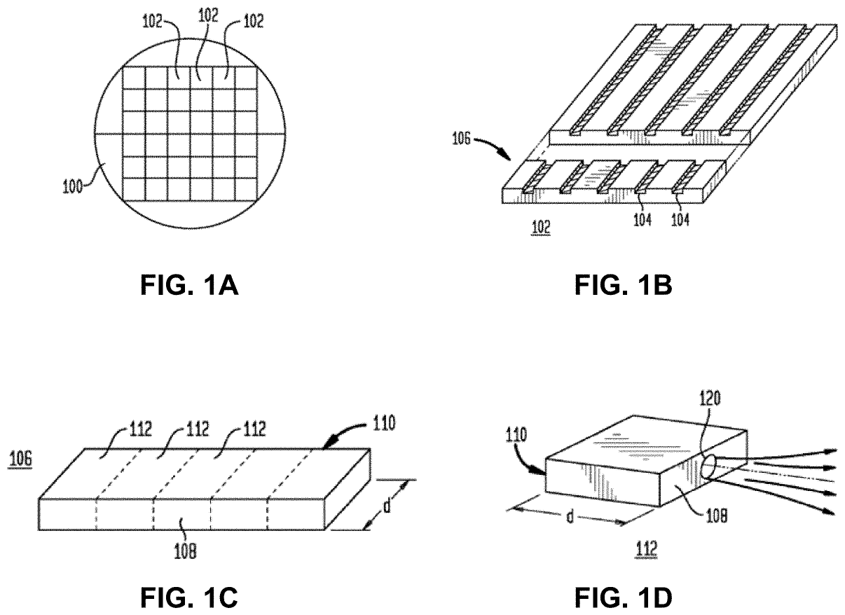

FIGS. 1A-1D are diagrams of an example process for manufacturing a semiconductor laser device. For example, as shown in FIG. 1A, layered structures used in semiconductor lasers may be formed on a substrate wafer 100 using a stripe-geometry technique that yields edge emitting lasers. The layered structures may be arranged on the wafer 100 as rectangular blocks 102, wherein the wafer 100 is cleaved (e.g., separated) after the layered structures have been formed. For example, FIG. 1B shows an example of an individual block 102 cleaved from the wafer 100. The block 102 has multiple laser-diode stripes 104, each of which may have a width of about a few micrometers (μm) and a thickness of about one μm, and the separation between adjacent stripes 104 is about a few hundred μm. As further shown in FIG. 1B, a block 102 cleaved from the wafer 100 may be further cleaved into multiple laser bars 106.

For example, FIG. 1C illustrates an example of an individual laser bar 106 cleaved or otherwise separated from a block 102 that includes multiple laser-diode stripes 104. As shown, the laser bar 106 includes a front facet 108 and a rear facet 110, where the front facet 108 and the rear facet 110 are coated with materials having relatively low and/or high reflection coefficients. The coated facets 108 and 110 together with the corresponding laser-diode stripe 104 define a laser cavity for each laser device 112 of the laser bar 106. The wavelength of the light generated by each individual laser device 112 may be based on a length of the laser cavity, d, among other parameters, where a typical cavity length can be in a range from about 100 μm to about 10,000 μm. As further shown in FIG. 1D, a laser device 112 can be separated from a laser bar 106 (e.g., the laser bar 106 may be singulated into laser devices 112), and light generated within the laser cavity exits through the facet 108 to form a laser beam 120 when appropriate voltages are applied to the laser device 112.

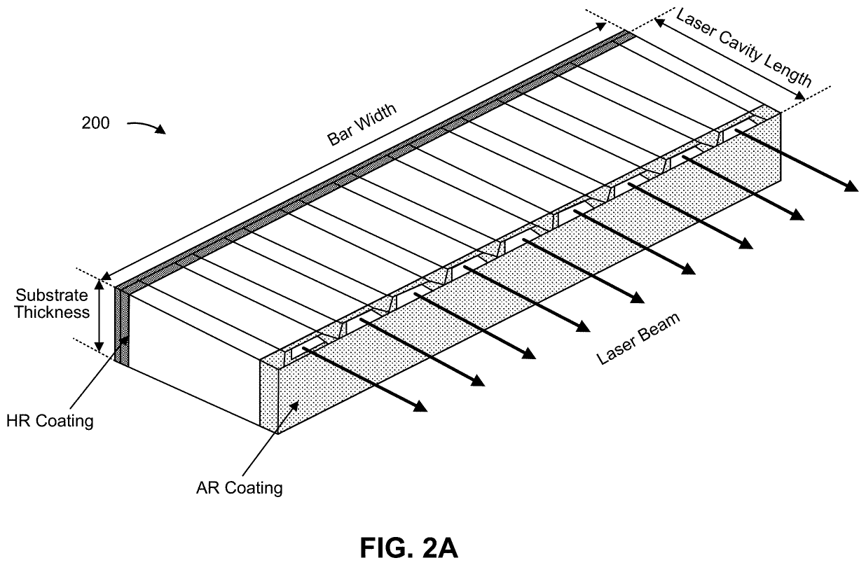

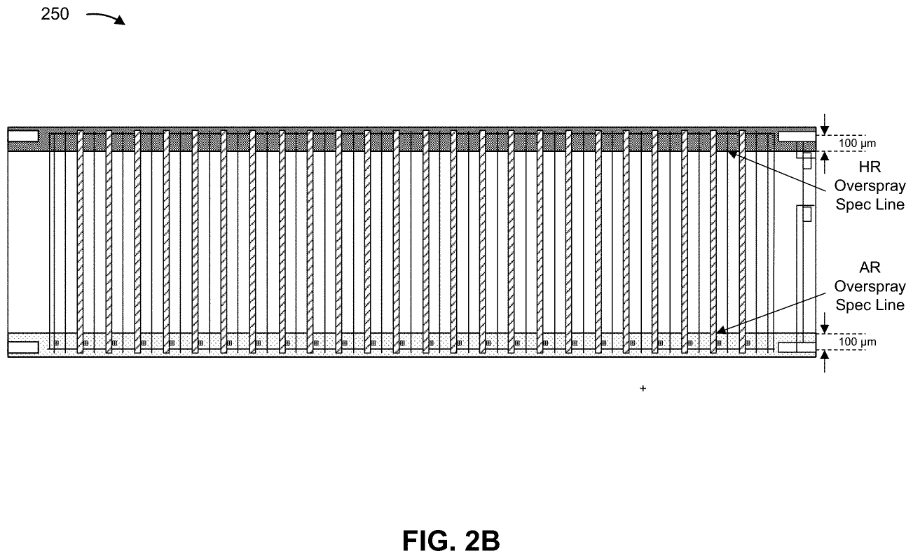

FIG. 2A is a diagram of an example of a laser strip device 200 that has a first optical coating on a first facet and a second optical coating on a second facet. In some implementations, the laser strip device 200 may correspond to the laser bar 106 described above with reference to FIGS. 1A-1D. As described herein, the optical coatings applied to the facets of the laser strip device 200 may include one or more thin layers of material that are deposited on a lens, mirror, or other optical component to alter the way in which the optical component reflects and transmits light (e.g., a laser beam) to satisfy specific application needs. For example, an anti-reflective (AR) coating increases transmission to reduce unwanted surface reflections, and a highly reflective (HR) coating (sometimes called a mirror coating) increases surface reflectance and can create mirrors that reflect virtually all light that falls on the HR coating within a given wavelength range. In the example shown in FIG. 2A, the laser strip device 200 includes an AR coating on a front facet and an HR coating on a rear facet, where the AR coating and the HR coating may be applied to the facets via ion evaporation, sputtering, ion beam deposition, and/or other suitable processes. In some cases, the deposition process used to apply the AR coating and/or the HR coating may result in overspray, which generally refers to a portion of the AR coating and/or the HR coating that covers beyond a target area. Accordingly, because the overspray may have adverse effects (e.g., interfering with bonding pads used for mechanical and/or electrical connections), an overspray specification is sometimes used to verify that the overspray does not exceed fabrication requirements (e.g., to protect mechanical or electrical bonding and/or to avoid delamination or loss of ohmic contact).

For example, FIG. 2B is a diagram illustrating an example overspray specification 250 that shows an extent to which the overspray portion of the AR coating and/or the HR coating is allowed to cover the sides of the laser facets. For example, in FIG. 2B, the overspray specification 250 is shown from a top-view of a single laser bar and includes an AR overspray specification line and an HR overspray specification line, where the AR overspray specification line and the HR overspray specification line represent a maximum overspray (e.g., ≤100 micrometers (μm)) from laser cleaving facets (e.g., the distance between the laser cleave facets and the AR/HR overspray specification lines is 100 μm). Conventionally, the overspray on the sides of the laser facets is inspected by measuring the overspray under a high-powered microscope on every individual laser bar. For example, overspray control for the AR/HR coatings on the sides of laser facets currently relies on post-deposition visual inspection on every single laser bar, where a high-magnification microscope is used to measure the overspray distance from the laser facet. The conventional techniques used to perform overspray screening are neither practical nor time or cost-effective. For example, in cases where AR/HR coating deposition is performed at a first facility, but visual inspection is performed at a second facility, feedback from the second facility to the first facility about misprocessing causing overspray to be out-of-specification (OOS) would significantly delay any process correction at the first facility where the AR/HR coating deposition is performed.

Some implementations described herein relate to a microruler that may be patterned on a surface of a wafer to enable overspray screening. For example, a laser bar cleaved from a wafer may comprise multiple laser devices that each include a first facet and a second facet, an AR coating applied to the first facet, and an HR coating applied to the second facet. Furthermore, a set of microrulers may be patterned on a surface of the laser bar, where each microruler in the set of microrulers is aligned with a bar cleaving line where the laser bar was, or will be, cleaved from the wafer, and each microruler has multiple graduation markings that each represent a respective distance from the bar cleaving line such that the graduation markings can be used to quantitatively measure an overspray of the AR coating or the HR coating relative to the bar cleaving line. For example, in some implementations, the graduation markings may include a set of major graduation markings that are patterned at intervals from the bar cleaving line up to a maximum allowable distance for the overspray of the AR coating or the HR coating. In some implementations, in addition to the major graduation markings, the graduation markings may include multiple sets of minor graduation markings at increments between adjacent major graduation markings. In some implementations, the microruler may include text markings that are adjacent to the major and/or minor graduation markings to indicate the respective distances from the bar cleaving line. In some implementations, one or more overspray specification lines may also be patterned on the surface of the laser bar to indicate the maximum allowable distance for the overspray of the AR coating or the HR coating.

Accordingly, the microruler described herein may enable bar-level overspray screening (e.g., at a thin film coating facility after an AR coating and/or an HR coating is applied at the thin film coating facility). In this way, the overspray can be clearly and easily observed, and quantitatively measured, on the microruler to determine whether the overspray is over the specification line, whereby any low-power microscope with a top-down (e.g., birds-eye) view (e.g., with a ˜30× or ˜50× magnification) can be used to perform the overspray screening. Accordingly, in cases where overspray screening is performed at the thin film coating facility, any out-of-specification (OOS) laser bars can be removed, which saves materials and logistic costs otherwise associated with sending misprocessed bars for continued processing or qualification. Additionally, the microruler provides instant feedback to improve a mirror coating process and/or perform a failure analysis for the mirror coating process, including a design of a sample loading fixture (e.g., a sample holder of laser bars to control the AR and/or HR coating with a desired deposition angle and overspray specification). Furthermore, in cases where visual inspection for overspray screening is performed at another facility, the visual inspection may be performed according to a work instruction to perform the overspray screening using the microruler to improve accuracy and to save time, labor, and/or costs. In addition, removing the OOS overspray samples may avoid downstream back-end (BE) assembly process failure and/or compromised device reliability.

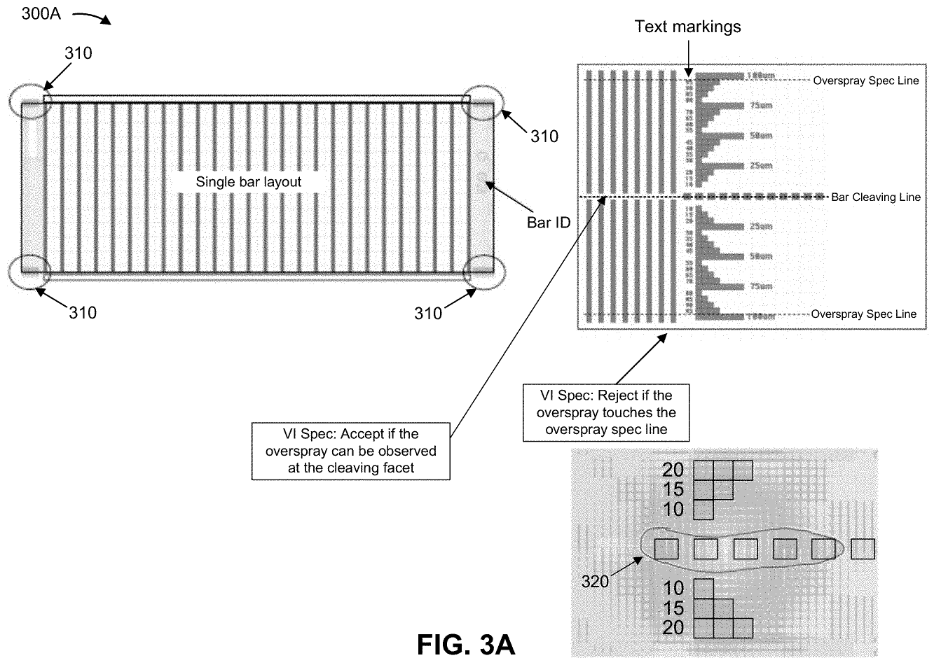

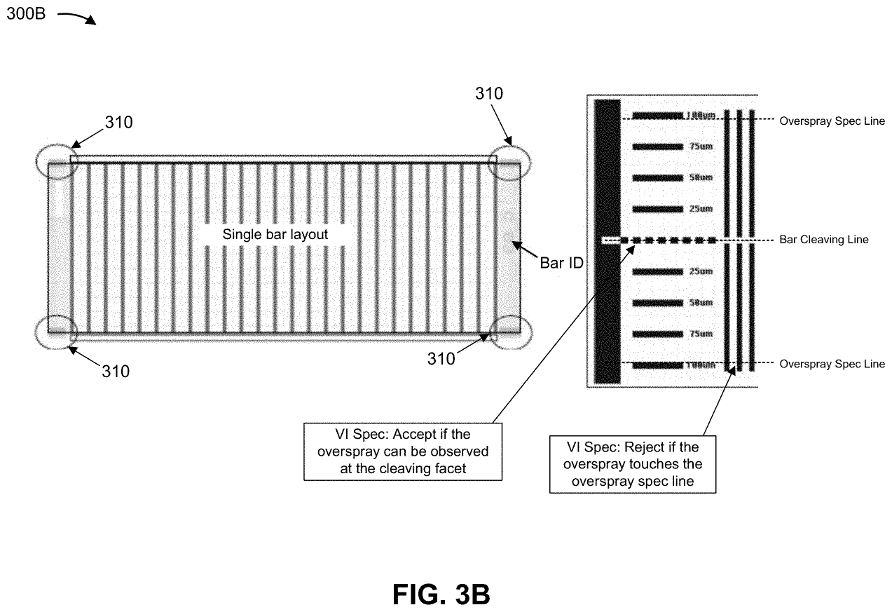

FIGS. 3A-3B are diagrams of one or more example implementations 300A, 300B of a microruler that may be patterned on a surface of a laser device to enable overspray screening for an AR coating and/or an HR coating applied to one or more facets of the laser device. As described herein, examples 300A, 300B relate to wafer-level microruler designs that may be used for a laser bar (e.g., a one-dimensional array of laser devices that includes multiple laser devices and/or multiple laser stripes) with overspray specification lines of +/−100 μm relative to a bar cleaving line (e.g., the overspray of an AR coating and/or an HR coating cannot exceed 100 μm from the bar cleaving line). However, it will be appreciated that any suitable value can be used for the maximum allowable distance of the overspray from the bar cleaving line, which may be visually inspected and/or quantitatively measured using the microruler designs described herein (e.g., to provide specific process feedback, such as a specific amount of overspray and/or underspray, in addition to or separate from visual inspection for compliance with overspray requirements). In some implementations, as described herein, a wafer may be cleaved into multiple laser bars along one or more bar cleaving lines, where each laser bar includes multiple laser devices. Each laser bar may then be sprayed or otherwise subjected to a process in which an AR coating and/or an HR coating is applied to one or more facets on the sides of the laser bars, and the laser bars may be visually inspected using the microruler to verify that the coating does not exceed the overspray specification line. In some implementations, any laser bars that pass the visual inspection may then be singulated into individual laser devices, as described elsewhere herein. Alternatively, if one or more laser bars fail the visual inspection, appropriate process correction may be employed at the facility where the AR coating and/or HR coating is applied.

In some implementations, in the example 300A shown in FIG. 3A, the microruler includes a set of major graduation markings that are patterned at intervals from the bar cleaving line up to a maximum allowable distance for the overspray of the AR coating or the HR coating, and multiple sets of minor graduation markings that are patterned at increments between adjacent major graduation markings. For example, in FIG. 3A, the major graduation markings are shown as longer lines or rectangular boxes that represent distances of 25 μm, 50 μm, 75 μm, and 100 μm from the bar cleaving line, and the minor graduation markings scale in 5 μm increments between adjacent sets of major graduation markings (e.g., between a first major graduation marking representing a 25 μm distance from the bar cleaving line and a second major graduation marking representing a 50 μm distance from the bar cleaving line, there may be four minor graduation markings to represent distances of 30 μm, 35 μm, 40 μm, and 45 μm from the bar cleaving line). Accordingly, in an example where the maximum overspray distance is 100 μm from the bar cleaving line, the laser bar may be rejected if a visual inspection indicates that the overspray of an AR/HR coating touches or goes over the overspray specification line. Additionally, or alternatively, a visual inspection instruction may indicate that the laser bar is accepted if the overspray can be observed at the cleaving facet (e.g., indicating that the AR and/or HR coating fully covers the cleaving facet). In another design, as shown by example 300B in FIG. 3B, the microruler includes only major graduation markings.

In some implementations, the microruler may be imprinted or otherwise patterned on a wafer (e.g., at a wafer-level), and is generally aligned with the bar cleaving line for the laser bar (e.g., zero (0) on the microruler is aligned with the bar cleaving line). For example, to pattern the microruler on the wafer and align the microruler with the bar cleaving line, the microruler may be defined at the same layer as the laser cleaving facet (e.g., for improved accuracy by avoiding an alignment tolerance error that would otherwise arise between each separate step when the next layout or mask is aligned over the wafer). For example, in some implementations, the microruler and the laser cleaving facet may be defined at a laser waveguide formation layer photolithography step. Accordingly, in some implementations, a process flow to make a laser bar with an imprinted wafer-level microruler patterned on a surface of the laser bar may include cleaning a wafer, performing a first nitride deposition, performing a waveguide formation layer photolithography step to pattern the microruler and optional overspray specification lines on the wafer, performing a first nitride plasma etch, and then applying a resist strip.

As shown in FIG. 3A and FIG. 3B, a portion of a wafer representing a single laser bar layout is shown along with small portions of eight (8) other laser bars that surround the laser bar on the wafer, where the laser bar layout includes various laser devices (e.g., the single bar layout being one of the laser strip devices) with microrulers (the encircled rectangles depicted by reference number 310). For the single bar layout shown in FIG. 3, there are four (4) microrulers, one (1) in each corner of the single laser bar, which is divided by vertical and horizontal bar cleaving lines. The exploded view on the right-hand side illustrates the features of the microrulers in one of the circles. It will be appreciated, however, that only half of the features of the microruler shown in the exploded view will remain on the laser bar after bar cleaving (e.g., either the top half, from the bar cleaving line to the top overspray specification line, or the bottom half, from the bar cleaving line to the bottom overspray specification line, depending on the corner of the laser bar in which the microruler appears).

As shown in FIG. 3A and FIG. 3B, the bar cleaving line is a line along which the laser bars will be cut from the wafer. Above the bar cleaving line is a first laser bar with a corresponding first microruler, and below the bar cleaving line is a second laser bar with a corresponding second microruler. As shown in FIG. 3A and FIG. 3B, the microruler provides various graduation markings from a location where the facet will be after cleaving up to the overspray specification line, which is the maximum allowable distance for the overspray of the AR coating or the HR coating. As shown in FIG. 3A and FIG. 3B, the microruler includes major graduation markings every 25 μm in the form of long horizontal lines for 25 μm, 50 μm, 75 μm, and 100 μm. As shown in FIG. 3A, the microruler may additionally include multiple sets of minor graduation markings at increments between adjacent major graduation markings (e.g., every 5 μm). In some implementations, the minor graduation markings may have an accumulative shape, shown as accumulative square boxes in FIG. 3A (e.g., one square box for a 5 μm increment from a lower major graduation marking, two square boxes for a 10 μm increment from the lower major graduation marking, three square boxes for a 15 μm increment from the lower major graduation marking, and four square boxes for a 20 μm increment from the lower major graduation marking). As shown in FIG. 3A and FIG. 3B, the microruler may also have text markings that are adjacent to the graduation markings to indicate the distance from the bar cleaving facet for the major and/or minor graduation markings. Furthermore, as shown in FIG. 3A, the first minor graduation marking that is closest to the bar cleaving line (e.g., +/−5 μm from the bar cleaving line) is omitted to avoid interfering with cleaving boxes along the center bar cleaving line, as shown by reference number 320. In some implementations, any suitable scale of measurement can be used for the initial graduation marking (e.g., a smallest scale of resolution needed to perform overspray screening for the specific device on which the microruler is patterned). For example, although the minor graduation markings are provided in 5 μm increments in FIG. 3A, the microruler may begin with a 1 μm graduation marking or another suitable value up to a maximum number of micrometers to be monitored. Additionally, or alternatively, the minor graduation markings may be omitted (e.g., the microruler may include only major graduation markings at 25 μm increments or other suitable increments, as in FIG. 3B).

In some implementations, the microruler may be provided for a 100 μm overspray specification line, a 60 μm overspray specification line, a 30 μm overspray specification line, or any other desired distance. Furthermore, in some implementations, the microruler may include a minimum overspray specification line representing a minimum distance of the overspray from the bar cleaving line. In this way, in addition to being used to visually inspect whether the AR and/or HR coatings applied to a laser bar pass the overspray screening (e.g., do not exceed the overspray specification line) or are OOS (e.g., exceed the overspray specification line), the microruler may also be used to visually inspect whether the AR and/or HR coatings on the side satisfy (e.g., are over) a minimum overspray. Accordingly, because the minimum overspray may be different for different devices, the microruler may have a range that provides a minimum-maximum scale that enables a visual inspection to screen out OOS parts (e.g., where the overspray may be required to exceed the minimum overspray specification line and required to not exceed the maximum overspray specification line). In some implementations, in cases where a device requires a 1 μm minimum overspray, which is close to the limit that optical microscopes can handle, different visual inspection methods or visual inspection instructions may be provided for visually inspecting the minimum overspray.

In some implementations, the microruler described herein can be applied to either a p-side of a wafer or an n-side of a wafer for mirror coating overspray screening. In general, only one side of the wafer is patterned to apply the microruler (e.g., the p-side or top side in examples 300A, 300B), while the other side (e.g., the n-side or backside) requires wafer thinning or lapping to remove any pattern that was applied. However, in cases where the thinned wafer is run through another layer of lithography, the other side of the wafer may be patterned with additional processing. Alternatively, if a reversed image microscope is available, the backside image will appear to map on the front side during visual inspection, in which case the overlay images between the p-side microruler and the n-side overspray (e.g., assuming a high accuracy alignment) could be used to perform the same pass/fail overspray screening by observing the microruler overlaid on the backside.

In some implementations, the microruler described herein may be printed on a dielectric layer (e.g., a silicon nitride (SiN) layer) to provide a better visual contrast. Alternatively, in some implementations, the microruler may be printed on a metal layer, in which case the microruler may not be very precisely aligned with the laser facet after bar cleaving (although the microruler could be accurate enough to perform such overspray screening, as the layer-to-layer overlay printed by a stepper (e.g., a metal layer to a waveguide layer) can be less than 1 μm. In some implementations, the microruler can also be used for other purposes, such as controlling and/or inspecting an epoxy reflow line, a polishing facet ending line, and/or a dicing fiducial used for precise facet alignment.

As indicated above, FIGS. 3A-3B are provided as one or more examples. Other examples may differ from what is described with regard to FIGS. 3A-3B.

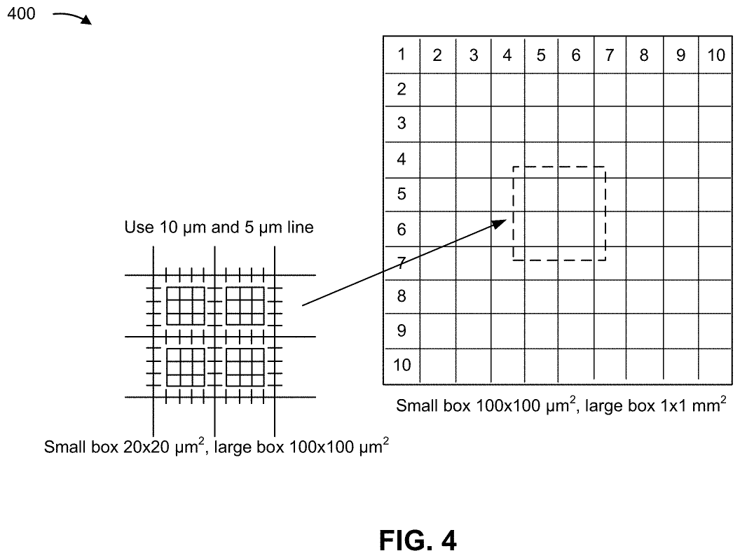

FIG. 4 is a diagram of an example implementation of a two-dimensional (2D) microruler 400 that can be used for wire-bonding, laser welding, and/or epoxy contact area screening. For example, in some implementations, the 2D microruler 400 shown in FIG. 4 may be used for area of contact screening. As shown in FIG. 4, the 2D microruler 400 may include graduation markings in two dimensions, resulting in a grid that includes various smaller boxes enclosed within a larger box. For example, the 2D microruler 400 may be printed on a device to be screened using similar techniques as described elsewhere herein, and may be defined as a grid in which each coordinate represents a distance from an origin in two dimensions. For example, in FIG. 4, an origin of the 2D microruler 400 is defined at an upper left-corner of a larger box that is one square millimeter (although any suitable length may be used), and each smaller box is 100 μm². Accordingly, in FIG. 4, the dashed box in the center of the 2D microruler 400 spans an area from about 400 μm to about 600 μm from the origin on an x-axis and about 400 μm to about 600 μm from the origin on a y-axis. Furthermore, to provide finer granularity, each smaller box in the grid may include additional graduation markings and/or sub-features to refine the measurement. For example, as shown in FIG. 4, a 100 μm² box in the larger grid may include nine (9) smaller boxes that are each 20 μm², with graduation markings provided along a perimeter of the 100 μm² box to measure distances of less than 20 μm (or another suitable value depending on the scale used for the 2D microruler 400). In the particular design shown in FIG. 4, the line width can be 10 μm for the 100×100 μm² square perimeter, and 5 μm for the 20×20 μm² square perimeter. In some embodiments, microrulers that are two-dimensional may be adjacent to a cleaving or dicing line similar to the microrulers described above for measuring facet coating overspray, or the 2D microrulers may be located on the surface of a wafer without association with a cleaving or dicing line or without association with an edge or facet of a bar of the wafer. In this way, the 2D microruler 400 can be used to extend the microruler design to area of contact screening applications such as wire-bonding, laser welding, and/or epoxy contact area screening.

As indicated above, FIG. 4 is provided as an example. Other examples may differ from what is described with regard to FIG. 4.

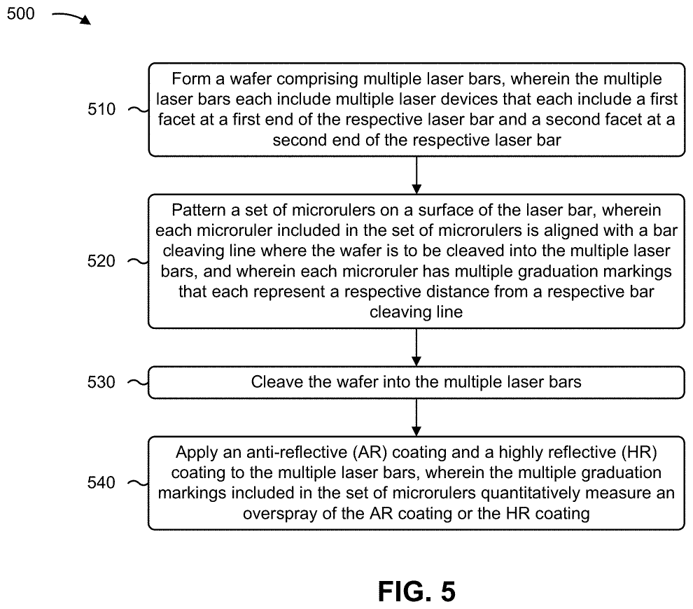

FIG. 5 is a flowchart of an example process 500 to fabricate laser bars that have a microruler patterned on a surface of the laser bars to enable overspray screening for an AR coating and/or an HR coating applied to one or more facets of the laser bars. In some implementations, one or more process blocks of FIG. 5 are performed by manufacturing equipment at a thin film coating facility.

As shown in FIG. 5, process 500 may include forming a wafer comprising multiple laser bars, wherein the multiple laser bars each include multiple laser devices that each include a first facet at a first end of the respective laser bar and a second facet at a second end of the respective laser bar (block 510).

As further shown in FIG. 5, process 500 may include patterning a set of microrulers on a surface of the laser bar, wherein each microruler included in the set of microrulers is aligned with a bar cleaving line where the wafer is to be cleaved into the multiple laser bars, and wherein each microruler has multiple graduation markings that each represent a respective distance from a respective bar cleaving line (block 520).

As further shown in FIG. 5, process 500 may include cleaving the wafer into the multiple laser bars (block 530).

As further shown in FIG. 5, process 500 may include applying an AR coating and an HR coating to the multiple laser bars, wherein the multiple graduation markings included in the set of microrulers quantitatively measure an overspray of the AR coating or the HR coating (block 540).

Process 500 may include additional implementations, such as any single implementation or any combination of implementations described below and/or in connection with one or more other processes described elsewhere herein.

In a first implementation, the multiple graduation markings include a set of major graduation markings that are patterned at intervals from a bar cleaving line up to a maximum allowable distance for the overspray of the AR coating or the HR coating.

In a second implementation, alone or in combination with the first implementation, the multiple graduation markings include multiple sets of minor graduation markings at increments between adjacent major graduation markings.

In a third implementation, alone or in combination with one or more of the first and second implementations, a minor graduation marking that is closest to the bar cleaving line is omitted from the multiple sets of minor graduation markings.

In a fourth implementation, alone or in combination with one or more of the first through third implementations, the minor graduation markings are patterned as accumulative shapes between the adjacent major graduation markings.

In a fifth implementation, alone or in combination with one or more of the first through fourth implementations, one or more overspray specification lines are patterned on the surface of the laser bar to indicate one or more of a minimum required distance or the maximum allowable distance for the overspray of the AR coating or the HR coating.

In a sixth implementation, alone or in combination with one or more of the first through fifth implementations, each microruler has text markings, adjacent to the multiple graduation markings, to indicate the respective distance from the bar cleaving line.

In a seventh implementation, alone or in combination with one or more of the first through sixth implementations, the set of microrulers and the bar cleaving line are patterned on a same layer of the wafer.

In an eighth implementation, alone or in combination with one or more of the first through seventh implementations, the set of microrulers includes four microrulers that are each patterned at a respective corner of the laser bar.

In a ninth implementation, alone or in combination with one or more of the first through eighth implementations, wherein the set of microrulers are patterned on a dielectric layer.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel. For example, in cases where the microruler is a 2D microruler (e.g., as shown in FIG. 4), the 2D microruler may be printed or patterned on a device that is not associated with a cleaving line or a facet edge. Accordingly, in such cases, the 2D microruler may be printed or patterned (e.g., with graduation markings in two dimensions) on a device to be screened to define a grid in which each coordinate represents a distance from an origin in two dimensions. For example, as described above with reference to FIG. 4, a 2D microruler may be patterned adjacent to a cleaving or dicing line or located on the surface of a wafer without association with a cleaving or dicing line or without association with an edge or facet of a bar of the wafer.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” “rear,” “front,” or the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees, 180 degrees, or at other orientations) and the spatially relative descriptors used herein may likewise be interpreted accordingly.

What is claimed is:

1. A laser bar, comprising:
multiple laser devices that each include a first facet at a first end of the laser bar and a second facet at a second end of the laser bar;
an anti-reflective (AR) coating applied to the first end of the laser bar;
a highly reflective (HR) coating applied to the second end of the laser bar; and
a set of microrulers patterned on a surface of the laser bar,
wherein each microruler included in the set of microrulers is aligned with a bar cleaving line where the laser bar was cleaved from a wafer, and
wherein each microruler has multiple graduation markings that each represent a respective distance from the bar cleaving line for quantitatively measuring an overspray of the AR coating or the HR coating relative to the bar cleaving line.

2. The laser bar of claim 1, wherein the multiple graduation markings include a set of major graduation markings that are patterned at intervals from the bar cleaving line up to a maximum allowable distance for the overspray of the AR coating or the HR coating.

3. The laser bar of claim 2, wherein the multiple graduation markings include multiple sets of minor graduation markings at increments between adjacent major graduation markings.

4. The laser bar of claim 3, wherein a minor graduation marking that is closest to the bar cleaving line is omitted from the multiple sets of minor graduation markings.

5. The laser bar of claim 3, wherein the minor graduation markings are patterned as accumulative shapes between the adjacent major graduation markings.

6. The laser bar of claim 2, further comprising:
one or more overspray specification lines patterned on the surface of the laser bar to indicate one or more of a minimum required distance or the maximum allowable distance for the overspray of the AR coating or the HR coating.

7. The laser bar of claim 1, wherein each microruler has text markings, adjacent to the multiple graduation markings, to indicate the respective distances from the bar cleaving line.

8. The laser bar of claim 1, wherein the set of microrulers and the bar cleaving line are patterned on a same layer of the wafer.

9. The laser bar of claim 1, wherein the set of microrulers includes four microrulers that are each patterned at a respective corner of the laser bar.

10. The laser bar of claim 1, wherein the set of microrulers are patterned on a dielectric layer.

11. A laser device, comprising:
a laser cavity;
a first facet at a first end of the laser cavity;
a second facet at a second end of the laser cavity;
an anti-reflective (AR) coating applied to the first facet at the first end of the laser cavity;
a highly reflective (HR) coating applied to the second facet at the second end of the laser cavity; and
a set of microrulers patterned on a surface of the laser device,
wherein each microruler included in the set of microrulers is aligned with a location of the first facet or the second facet, and
wherein each microruler has multiple graduation markings that each represent a respective distance from the location of the first facet or the second facet for quantitatively measuring an overspray of the AR coating or the HR coating.

12. The laser device of claim 11, wherein the multiple graduation markings include a set of major graduation markings that are patterned at intervals from the location of the first facet or the second facet up to a maximum allowable distance for the overspray of the AR coating or the HR coating.

13. The laser device of claim 12, wherein the multiple graduation markings include multiple sets of minor graduation markings at increments between adjacent major graduation markings.

14. The laser device of claim 13, wherein a minor graduation marking that is closest to the location of the first facet or the second facet is omitted from the multiple sets of minor graduation markings.

15. The laser device of claim 13, wherein the minor graduation markings are patterned as accumulative shapes between the adjacent major graduation markings.

16. The laser device of claim 11, wherein each microruler has text markings, adjacent to the multiple graduation markings, to indicate the respective distance from the location of the first facet or the second facet.

17. A method, comprising:
forming a wafer comprising multiple laser bars, wherein the multiple laser bars each include multiple laser devices that each include a first facet at a first end of the respective laser bar and a second facet at a second end of the respective laser bar;
patterning a set of microrulers on a surface of the laser bar,
wherein each microruler included in the set of microrulers is aligned with a bar cleaving line where the wafer is to be cleaved into the multiple laser bars, and
wherein each microruler has multiple graduation markings that each represent a respective distance from a respective bar cleaving line;
cleaving the wafer into the multiple laser bars; and
applying an anti-reflective (AR) coating and a highly reflective (HR) coating to the multiple laser bars, wherein the multiple graduation markings included in the set of microrulers quantitatively measure an overspray of the AR coating or the HR coating.

18. The method of claim 17, wherein the multiple graduation markings include a set of major graduation markings that are patterned at intervals from a bar cleaving line up to a maximum allowable distance for the overspray of the AR coating or the HR coating.

19. The method of claim 17, wherein the multiple graduation markings include multiple sets of minor graduation markings at increments between adjacent major graduation markings.

20. The method of claim 17, wherein each microruler has text markings, adjacent to the multiple graduation markings, to indicate the respective distance from the bar cleaving line.
